(19) United States
(12) Patent Application Publication
(10) Pub. No.: US 2017/0206919 A1
(43) Pub. Date: Jul. 20, 2017

(54) MAGNETIC RECORDING MEDIUM AND METHOD FOR PRODUCING SAME

(71) Applicant: FUJI ELECTRIC CO., LTD., Kawasaki-shi (JP)

(72) Inventors: Akira Furuta, Sendai-shi (JP); Hiroto Kikuchi, Sendai-shi (JP); Hiroyasu Kataoka, Sendai-shi (JP); Takehito Shimatsu, Sendai-shi (JP)

(21) Appl. No.: 15/476,466

(22) Filed: Mar. 31, 2017

Related U.S. Application Data
(63) Continuation of application No. PCT/JP2015/004860, filed on Sep. 24, 2015.

(30) Foreign Application Priority Data
Nov. 20, 2014 (JP) 2014-235894

(51) Int. Cl. G11B 5/66; C23C 14/14; G11B 5/851; G11B 5/65; G11B 5/82

(52) U.S. Cl. CPC G11B 5/66; G11B 5/653; G11B 5/656; G11B 5/82; G11B 5/851; C23C 14/14

(57) ABSTRACT

The purpose of the present invention is to provide a magnetic recording medium making secondary growth of magnetic crystal grains inhibited, having a magnetic recording layer having a large film thickness, and exhibiting excellent magnetic characteristics, and to provide a method for producing the medium. A magnetic recording medium according to the present invention includes a substrate and a magnetic recording layer that includes a lower layer and an upper layer, in which the lower layer and the upper layer include magnetic crystal grains formed of an ordered alloy and non-magnetic grain boundaries, the lower layer is formed by depositing Bi, C and an element constituting the ordered alloy, and the upper layer is formed by depositing C and an element constituting the ordered alloy. The present invention also provides a method for producing the above-described magnetic recording medium.

### CROSS-REFERENCE TO THE RELATED APPLICATIONS

This application is a continuation application of PCT Application No. PCT/JP2015/004860 filed on Sep. 24, 2015 under 37 Code of Federal Regulation §1.53 (b) and the PCT application claims the benefit of Japanese Patent Application No. 2014-235894 filed on Nov. 20, 2014, all of the above applications being hereby incorporated by reference wherein in their entirety.

### BACKGROUND OF THE INVENTION

Field of the Invention

The present invention relates to a magnetic recording medium and a method for producing the same. In particular, the present invention relates to a magnetic recording medium used in a hard disc magnetic recording device (HDD), and a method for producing the same.

Description of the Related Art

Perpendicular magnetic recording system is adopted as a technique for increasing the magnetic recording density. A perpendicular magnetic recording medium at least comprises a non-magnetic substrate and a magnetic recording layer formed of a hard-magnetic material. Optionally, the perpendicular magnetic recording medium may further comprise: a soft-magnetic under layer which is formed from soft-magnetic material and plays a role in concentrating the magnetic flux generated by a magnetic head onto the magnetic recording layer; an interlayer for orienting the hard-magnetic material in the magnetic recording layer in an intended direction; a protective film for protecting the surface of the magnetic recording layer; and the like.

The magnetic recording layer of the perpendicular magnetic recording medium formed of a granular magnetic material has been proposed for the purpose of obtaining good magnetic properties. The granular magnetic material comprises magnetic crystal grains and a non-magnetic crystal grain boundary segregated to surround the magnetic crystal grains. The respective magnetic crystal grains in the granular magnetic material are magnetically separated from each other with the non-magnetic crystal grain boundary.

For the purpose of further increasing the recording density of the perpendicular magnetic recording medium, a need for reduction in the grain diameter of the magnetic crystal grains in the magnetic layer arises in recent years. On the other hand, the reduction in the grain diameter of the magnetic crystal grains leads to a decrease in thermal stability of the recorded magnetization. Thus, the magnetic crystal grains in the magnetic layer need to be formed of a material with higher magnetocrystalline anisotropy, in order to compensate the decrease in thermal stability due to the reduction in the grain diameter of the magnetic crystal grains. As the material having the required higher magnetocrystalline anisotropy, L1₀ type ordered alloys have been proposed. Typical L1₀ type ordered alloys include FePt, CoPt, FePd, CoPd, and the like. On the other hand, carbon (C), boron (B), oxides and nitrides have been investigated as the material of the non-magnetic crystal grain boundary.

In the case of forming a magnetic recording layer comprising the L1₀ type ordered alloy, it is necessary to dispose respective atoms constituting the alloy to predetermined positions for achieving columnar growth. Especially in the case of forming a magnetic recording layer having a granular structure comprising the L1₀ type ordered alloy, it is necessary to separate magnetic crystal grains and a non-magnetic crystal grain boundary, in addition to the above-described disposition of the atoms. If a thin film of the material constituting the non-magnetic crystal grain boundary is formed onto the top surface of the magnetic crystal grain, “secondary growth” of the magnetic crystal grains occurs to lead to deterioration of properties of the magnetic recording layer. As used herein, “secondary growth” means a phenomenon that the magnetic crystal grain grown on the thin film of the material constituting the non-magnetic crystal grain boundary has a different orientation from that of the magnetic crystal grain positioned under the thin film. Therefore, intensive studies have been made in the point how the “secondary growth” is inhibited in the case of forming the magnetic recording layer having the granular structure.

On the other hand, methods for producing the magnetic recording layer comprising the L1₀ type ordered alloy with the use of Bi have been investigated. Japanese Patent Laid-Open No. 2004-134040 proposes a magnetic recording medium having a structure in which L1₀ type FePt nanoparticles are dispersed in a low melting matrix, and a method for producing the same. This magnetic recording medium is produced by a method comprising the steps of: heating and melting the low melting point matrix, thereby achieving ordering and c-axis orientation of the ordered alloy particles suspended in the matrix; and cooling and solidifying the low melting matrix in a magnetic field, thereby fixing the c-axis oriented ordered alloy particles in the state that the c-axis is directed toward a direction perpendicular to the surface of the substrate. The low melting matrix may comprise oxides such as B₂O₃, or metal such as Bi.

Japanese Patent Laid-Open No. 2004-178753 proposes an interlayer for a magnetic recording layer comprising an L1₀ type ordered alloy, which is formed of a material comprising: elements having equivalent lattice constants to that of the L1₀ type structure such as Pt, Pd, Rh and the like; and (1) high melting additional elements, (2) low melting additional elements, or (3) chemical compounds. In this proposal, it is explained that the low melting additional elements segregate at grain boundaries to promote separation of the magnetic crystal grains in the magnetic recording layer. The useful low melting additional elements include Bi, Mg, Al and the like.

In the above proposals, the properties of the magnetic recording layer are improved by utilizing the low melting point of Bi. However, utilization of other properties of Bi has been little investigated.

### SUMMARY OF THE INVENTION

It is required to obtain an ordered alloy having a good crystallinity. Further, there is a need for a magnetic recording medium having a structure in which the thickness of the magnetic recording layer can be increased while the secondary growth of magnetic crystal grains comprising the ordered alloy can be inhibited, and a method for producing the same.

The magnetic recording medium according to one embodiment comprises a substrate and a magnetic recording layer comprising a lower layer and an upper layer, wherein the lower layer and the upper layer comprise magnetic crystal grains consisting of an ordered alloy and a non-magnetic crystal grain boundary, the lower layer is formed by depositing Bi, C, and elements that constitute the ordered alloy, and the upper layer is formed by depositing C and elements that constitute the ordered alloy. Here, the ordered alloy may comprise at least one element selected from the group consisting of Fe and Co, and at least one element selected from the group consisting of Pt, Pd, Au, and Ir. Further, the ordered alloy may further comprise at least one element selected from the group consisting of Ni, Mn, Cu, Ag, Au, Ru and Cr. Preferably, the ordered alloy is L1₀ type FePt. Further, the lower layer may have a thickness of 0.1 nm or more and 3 nm or less.

The method for producing a magnetic recording layer according to another embodiment comprises the steps of: (1) preparing a substrate; (2) sputtering Bi, C, and element that constitute an ordered alloy to form a lower layer of a magnetic recording layer; and (3) sputtering C and the element that constitute the ordered alloy to form an upper layer of the magnetic recording layer. Here, the lower layer and the upper layer of the magnetic recording layer may comprise magnetic crystal grains consisting of the ordered alloy and a non-magnetic crystal grain boundary comprising C. Further, the ordered alloy may comprise at least one element selected from the group consisting of Fe and Co, and at least one element selected from the group consisting of Pt, Pd, Au, and Ir. Further, the ordered alloy may further comprise at least one element selected from the group consisting of Ni, Mn, Cu, Ag, Au, Ru and Cr. Preferably, the ordered alloy is L1₀ type FePt. Further, the lower layer may have a thickness of 0.1 nm or more and 3 nm or less.

An ordered alloy having good crystallinity can be provided. Further, a magnetic recording medium having a magnetic recording layer of a large thickness can be provided by inhibiting the secondary growth of magnetic crystal grains comprising the ordered alloy. The magnetic recording medium, having the magnetic recording layer in which the magnetic crystal grains are magnetically separated well from each other by the non-magnetic crystal grain boundary, exhibits good magnetic properties.

Further features of the present invention will become apparent from the following description of exemplary embodiments with reference to the attached drawings.

### BRIEF DESCRIPTION OF THE DRAWINGS

FIG. 1 is a schematic cross-sectional view showing one of configuration examples of the magnetic recording medium;

FIG. 2 is a schematic view for explaining the surfactant effect, FIGS. 2(a) to 2(e) being schematic views showing respective stages;

FIG. 3A is a graphical representation showing an M-H hysteresis loop of the magnetic recording medium of Example 6;

FIG. 3B is a graphical representation showing an M-H hysteresis loop of the magnetic recording medium of Comparative Example 6;

FIG. 4 is a graphical representation showing a relationship between the thickness of the magnetic recording layer and an α value, in the case where the C content in the upper layer is fixed;

FIG. 5 is a graphical representation showing a relationship between the C content in the upper layer and an α value, in the case where the thickness of the magnetic recording layer is fixed;

FIG. 6 is a graphical representation showing a relationship between the thickness of the lower layer and an α value, in the case where the thickness of the magnetic recording layer and the C content in the upper layer are fixed;

FIG. 7 is a graphical representation showing a relationship between the thickness of the lower layer and a net magnetic anisotropy constant of magnetic crystal grins Ku_grain, in the case where the thickness of the magnetic recording layer and the C content in the upper layer are fixed; and

FIG. 8 is a graphical representation showing a relationship between the thickness of the lower layer and coercive force Hc, in the case where the thickness of the magnetic recording layer and the C content in the upper layer are fixed.

### DESCRIPTION OF THE EMBODIMENTS

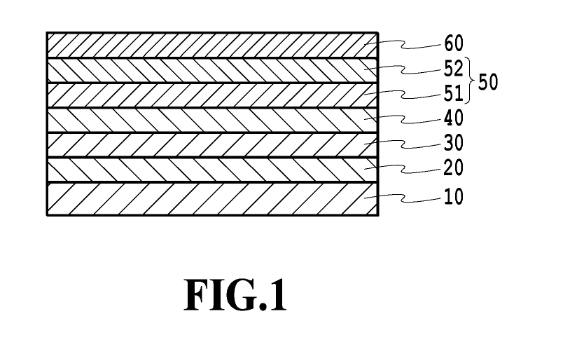

A magnetic recording medium comprises a substrate and a magnetic recording layer comprising a lower layer and an upper layer, wherein the lower layer and the upper layer comprise magnetic crystal grains consisting of an ordered alloy and a non-magnetic crystal grain boundary, the lower layer is formed by depositing Bi, C, and elements that constitute the ordered alloy, and the upper layer is formed by depositing C and elements that constitute the ordered alloy. The above-described magnetic recording medium may further comprise layers known in the art such as an adhesive layer, a soft-magnetic under layer, a heat sink layer, an interlayer, and/or a seed layer, between the substrate and the magnetic recording layer. In addition, the above-described magnetic recording medium may further comprise layers known in the art such as a protective layer and/or a liquid lubricant layer, on or above the magnetic recording layer. FIG. 1 shows one of constitutional examples of the magnetic recording medium, which comprises substrate 10, adhesive layer 20, interlayer 30, seed layer 40, magnetic recording layer 50 consisting of lower layer 51 and upper layer 52, and protective layer 60.

The substrate 10 may be various substrates having a flat surface. For example, the substrate 10 may be formed of material commonly used in magnetic recording media. The useful material includes a NiP-plated Al alloy, monocrystalline MgO, MgAl₂O₄, SrTiO₃, tempered glass, crystallized glass, and the like.

The adhesive layer 20, which may be formed optionally, is used for enhancing the adhesion between the layer formed on it and the layer formed under it. The layer formed under the adhesive layer 20 includes the substrate 10. The material for forming the adhesive layer 20 comprises a metal such as Ni, W, Ta, Cr or Ru, or an alloy containing the above-described metals. The adhesive layer 20 may be a single layer or have a stacked structure with plural layers.

The soft-magnetic under layer (not shown), which may be formed optionally, controls the magnetic flux emitted from a magnetic head to improve the read-write characteristics of the magnetic recording medium. The material for forming the soft-magnetic under layer includes: a crystalline material such as a NiFe alloy, a sendust (FeSiAl) alloy, or a CoFe alloy; a microcrystalline material such as FeTaC, CoFeNi or CoNiP; and an amorphous material including a Co alloy such as CoZrNb or CoTaZr. The optimum thickness of the soft-magnetic under layer depends on the structure and characteristics of the magnetic head used in magnetic recording. When forming the soft-magnetic under layer continuously with other layers, the soft-magnetic under layer preferably has a thickness in a range from 10 nm to 500 nm (both inclusive), in view of productivity.

A heat sink layer (not shown) may be provided when the magnetic recording medium is used in a heat-assisted magnetic recording system. The heat sink layer is a layer for effectively absorbing excess heat of the magnetic recording layer 50 generated during heat-assisted magnetic recording. The heat sink layer can be formed of a material having a high thermal conductivity and a high specific heat capacity. Such material includes a Cu simple substance, an Ag simple substance, an Au simple substance, or an alloy material composed mainly of these substances. As used herein, the expression “composed mainly of” means that the content of the concerned material is 50% by weight or more. In consideration of its strength or the like, the heat sink layer can be formed of an Al-Si alloy, a Cu-B alloy, or the like. Further, the heat sink layer can be formed of a sendust (FeSiAl) alloy, a soft-magnetic CoFe alloy, or the like. By using the soft-magnetic material, the function of concentrating a perpendicular magnetic field generated by the head can be imparted to the heat sink layer, and thereby the function of the soft-magnetic under layer can be complemented. The optimum thickness of the heat sink layer depends on the amount and distribution of heat generated during heat-assisted magnetic recording, as well as the layer configuration of the magnetic recording medium and the thickness of each constituent layer. When forming the heat sink layer continuously with other constituent layers, the heat sink layer preferably has a thickness of 10 nm or more and 100 nm or less, in view of productivity. The heat sink layer can be formed by any process known in the art, such as a sputtering method or a vacuum deposition method. Normally, the heat sink layer is formed by the sputtering method. The heat sink layer can be formed between the substrate 10 and the adhesive layer 20, between the adhesive layer 20 and the interlayer 30, or the like, in consideration of characteristics required for the magnetic recording medium.

The interlayer 30 is a layer for controlling the crystallinity and/or the crystalline orientation of the seed layer 40 formed thereon. The interlayer 30 may be a single layer or may consist of a plurality of layers. Preferably, the interlayer 30 is non-magnetic. The useful non-magnetic material for forming the interlayer 30 comprises a Pt metal, a Cr metal, or alloys in which at least one metal selected from the group consisting of Mo, W, Ti, V, Mn, Ta and Zr is added to the principal ingredient Cr. The interlayer 30 can be formed by any process known in the art, such as a sputtering method.

The function of the seed layer 40 is to control the grain diameter and the crystalline orientation of the magnetic crystal grains in the magnetic recording layer 50 which is the upper layer of the seed layer 40. The seed layer 40 may have a function to ensure the adhesion between the magnetic recording layer 50 and the layer underlying the seed layer 40. Alternatively, other layers such as an intermediate layer or the like can be disposed between the seed layer 40 and the magnetic recording layer 50. In the case where the intermediate layer or the like is disposed, the seed layer 40 has a function to control the grain diameter and the crystalline orientation of the crystal grains in the intermediate layer or the like, and thereby controlling grain diameter and the crystalline orientation of the magnetic crystal grains in the magnetic recording layer 50. The seed layer 40 is preferably non-magnetic. The material of the seed layer 40 is appropriately selected in accordance with the material of the magnetic crystal grains in the magnetic recording layer 50. If the magnetic crystal grains in the magnetic recording layer 50 is formed of the L1₀ type ordered alloy, the seed layer 40 is preferably formed of NaCl type compounds. Especially preferably, the seed layer 40 is formed of an oxide such as MgO, SrTiO₃, or the like, or a nitride such as TiN. In addition, the seed layer 40 can be formed by stacking a plurality of layers consisting of the above-described materials. The seed layer preferably has a thickness from 1 nm to 60 nm, more preferably from 1 nm to 20 nm, in view of improvement in crystallinity of the magnetic crystal grains in the magnetic recording layer 50, and improvement in productivity. The seed layer 40 can be formed by any process known in the art, such as a sputtering method.

The lower layer 51 of the magnetic recording layer 50 is formed by depositing C, Bi and elements constituting the ordered alloy. The resultant lower layer 51 has a granular structure consisting of magnetic crystal grains comprising the ordered alloy and a non-magnetic crystal grain boundary comprising C. Bi may exist in the magnetic crystal grains or in the non-magnetic crystal grain boundary. The ordered alloy comprises at least one element selected from the group consisting of Fe and Co, and at least one element selected from the group consisting of Pt, Pd, Au, and Ir. The preferable ordered alloy is an L1₀ type ordered alloy selected from the group consisting of FePt, CoPt, FePd, and CoPd. The ordered alloy may further comprise at least one element selected from the group consisting of Ni, Mn, Cu, Ag, Au, Ru and Cr, for modification of properties. Desirable modification of properties includes reduction in the temperature required for ordering of the L1₀ type ordered alloy. The especially preferable ordered alloy is L1₀ type FePt.

The lower layer 51 can be formed by sputtering Bi, C, and elements constituting the ordered alloy. As described herein, the step of “sputtering” means only a stage for ejecting atoms, clusters or ions from a target by collision of high-energy ions, and does not mean that all of elements contained in the ejected atoms, clusters or ions are fixed on the target substrate onto which a film is formed. In other words, the thin film obtained by the “sputtering” step described herein does not necessarily contain the element reaching the target substrate at the ratio of the reaching amount. In the formation of the lower layer 51, it is possible to use a target containing C and the elements constituting the ordered alloy at a predetermined ratio and a Bi target. Alternatively, a target containing the elements constituting the ordered alloy, a C target and a Bi target may be used. In the respective cases, the constituting ratio of the magnetic crystal grains and the non-magnetic crystal grain boundary can be controlled by adjusting electric power applied to the respective targets. By the way, the target containing the elements constituting the ordered alloy may be a set of a plurality of targets, each of which separately comprises an element for constituting the ordered alloy. The amount of Bi which reaches the target surface during formation of the lower layer 51 is preferably 1 to 50 atom % based on the total atoms which reaches the target surface. The addition amount of Bi can be adjusted by electric power applied to the Bi target.

Heating of the substrate is involved when the lower layer 51 is formed. In this case, the substrate temperature is within a range from 300° C. to 450° C. By adopting the substrate temperature within this range, it becomes possible to improve the order parameter of the ordered alloy in the lower layer 51.

Dependent on the amount of Bi reaching the target surface, the lower layer 51 has a thickness from 0.1 to 3 nm, preferably from 0.5 to 2 nm. By having the thickness within the above-described range, it is possible to obtain effects of improvement in magnetic separation of the magnetic crystal grains and inhibition of secondary growth of the magnetic crystal grains, throughout the whole of the magnetic recording layer 30.

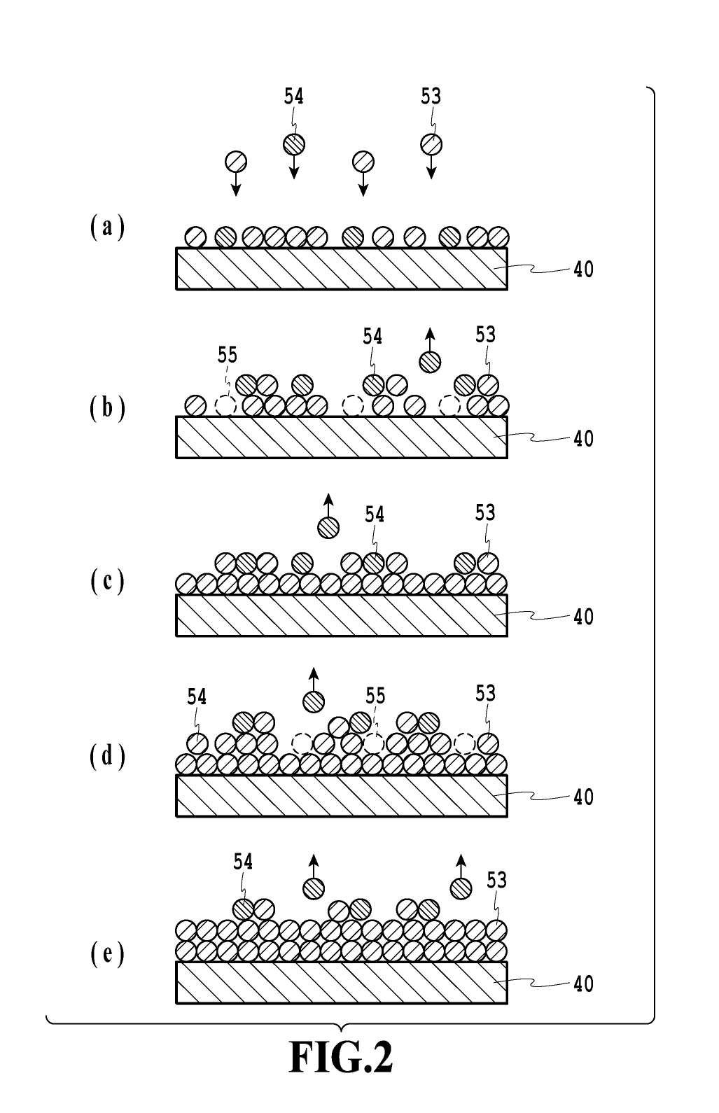

With reference to FIG. 2, “surfactant effect” during formation of the lower layer 51 will be explained. First, as shown in FIG. 2(a), the first layer is formed by depositing atoms constituting the granular structure 53 which consists of the ordered alloy and C, and surfactant atoms 54 which consists of Bi, onto the surface of the seed layer 40. When the deposition further continues, formation of the second layer begins as shown in FIG. 2(b). In this state, the surfactant atoms 54 existing in the first layer are migrated into the second layer to form voids 55 in the first layer. The reason of this phenomenon is considered that Bi has a low surface energy in comparison with C and the elements constituting the ordered alloy. Then, as shown in FIG. 2(c), rearrangement of the atoms in the first layer is promoted with the aid of the voids 55 formed in the first layer. In this stage, C atoms and the atoms constituting the ordered alloy which deposited at undesirable positions migrate to predetermined positions, to establish a structure comprising magnetic crystal grains separated from each other by the non-magnetic crystal grain boundary. In addition, part of the surfactant atoms 54 migrated to the second layer are re-evaporated and removed from the lower layer 51. Here, the process of removal from the lower layer 51 is not limited to re-evaporation. Subsequently, as shown in FIGS. 2(d) and (e), the migration of the surfactant atoms 54 between the second and third layers and the above-described rearrangement of the atoms in the second layer occur, as described above. As a result, C atoms and the atoms constituting the ordered alloy migrate to predetermined positions to establish a structure comprising magnetic crystal grains separated from each other by the non-magnetic crystal grain boundary. By repeating this process, the lower layer having a desired thickness can be obtained. Further, even if a C atom is deposited onto the magnetic crystal grain, the C atom will migrate to the non-magnetic crystal grain boundary due to the above-described surfactant effect. Therefore, the secondary growth of the magnetic crystal grain can be inhibited.

The upper layer 52 of the magnetic recording layer 50 is formed by sputtering C, and elements constituting the ordered alloy. The resultant upper layer 52 has a granular structure consisting of magnetic crystal grains comprising the ordered alloy and a non-magnetic crystal grain boundary comprising C. In the formation of the upper layer 52, similar targets to those used for the lower layer 51 can be used, except that the Bi target is not used. Further, the ordered alloy in the upper layer 52 and elements constituting the ordered alloy is similar to those for the lower layer 51. Besides, during formation of the upper layer 52, the surfactant effect due to Bi which remains on the uppermost surface of the lower layer 51 is exerted. Therefore, a structure comprising magnetic crystal grains separated from each other by the non-magnetic crystal grain boundary is also established, in the upper layer 52 having a larger thickness.

As described above, the remaining amount of Bi in the resultant magnetic recording layer 50 does not coincide with the amount of Bi reaching to the target surface during formation of the lower layer 51, since Bi which is the surfactant atom 54 is removed from the magnetic recording layer 50 by re-evaporation and the like. Further, it is considered that Bi remains in the non-magnetic crystal grain boundary, but Bi may remain in the magnetic crystal grains. Further, excessive retention of Bi may lead to reduction in saturated magnetization Ms and loss of magnetic spacing. Therefore, it is preferable to reduce the remaining amount of Bi as possible by raising the temperature during formation of the magnetic recording layer 50, that is, the lower layer 51 and the upper layer 52.

The magnetic recording layer 50 may further comprise one or more additional magnetic layers in addition to the lower layer 51 and the upper layer 52. Each of the one or more additional magnetic layers may have either of a granular structure or a non-granular structure. For example, an ECC (Exchange-Coupled Composite) structure may be formed by interposing a coupling layer such as Ru between the additional magnetic layer and the stacked structure which consists of the lower layer 51 and the upper layer 52. Alternatively, a magnetic layer not having a granular structure, as a continuous layer, may be disposed onto the stacked structure consisting of the lower layer 51 and the upper layer 52. The continuous layer comprises a so-called CAP layer.

The protective layer 60 can be formed of a material conventionally used in the field of magnetic recording media. Specifically, the protective layer 60 can be formed of non-magnetic metal such as Pt, a carbon-based material such as diamond-like carbon, or silicon-based material such as silicon nitride. The protective layer 60 may be a single layer or have a stacked structure. The stacked structure of the protective layer 60 may be a stacked structure of two types of carbon-based material having different characteristics from each other, a stacked structure of a metal and a carbon-based material, or a stacked structure of a metallic oxide film and a carbon-based material, for example. The protective layer 60 can be formed by any process known in the art such as a CVD method, a sputtering method (including a DC magnetron sputtering method or the like) or a vacuum deposition method.

Optionally, the magnetic recording medium may further comprise a liquid lubricant layer (not shown) disposed on the protective layer 60. The liquid lubricant layer can be formed of a material conventionally used in the field of magnetic recording media. For example, the material of the liquid lubricant layer comprises perfluoropolyether-based lubricants or the like. The liquid lubricant layer can be formed by a coating method such as a dip-coating method, a spin-coating method, or the like, for example.

### EXAMPLES 1-6

A chemically strengthened glass substrate having a flat surface (N-10 glass substrate manufactured by HOYA CORPORATION) was washed to prepare substrate 10. The washed substrate 10 was brought into an in-line type sputtering device. Then, Ta adhesive layer 20 having a thickness of 5 nm was formed by a DC magnetron sputtering method using a pure Ta target in Ar gas at a pressure of 0.5 Pa. The substrate temperature during formation of the Ta adhesive layer was room temperature (25° C.). The sputtering power during formation of the Ta adhesive layer was 100 W.

Next, Cr interlayer 30 having a thickness of 20 nm was formed by a DC magnetron sputtering method using a pure Cr target in Ar gas at a pressure of 0.5 Pa. The substrate temperature during formation of the Cr interlayer was room temperature (25° C.). The sputtering power during formation of the Cr interlayer was 300 W.

Next, MgO seed layer 40 having a thickness of 5 nm was formed by an RF magnetron sputtering method using an MgO target in Ar gas at a pressure of 0.1 Pa. The substrate temperature during formation of the MgO seed layer 40 was room temperature (25° C.). The sputtering power during formation of the MgO seed layer 40 was 200 W.

Next, the stacked body in which the MgO seed layer 40 had been formed was heated to a temperature of 430° C., and then lower layer 51 consisting of FePt-C-Bi was formed by a DC magnetron sputtering method using an FePt target, a C target, and a Bi target in Ar gas at a pressure of 1.5 Pa. The lower layer 51 had a thickness of 1 nm. The electric power applied to the targets during formation of the lower layer 51 was 40 W (FePt), 132 W (C), and 20 W (Bi), respectively. The resultant lower layer 51 comprised 25% by volume of C.

Subsequently, the stacked body in which the lower layer 51 had been formed was heated to a temperature of 430° C., and then upper layer 52 consisting of FePt-C was formed by a DC sputtering method using an FePt target and a C target in Ar gas at a pressure of 1.5 Pa, to form magnetic recording layer 50. The thickness of and the C content in the upper layer 52 were varied as described in Table 1, by controlling the duration of formation and the electric power applied to the targets.

Finally, Pt protective layer 60 having a thickness of 5 nm was formed by a DC magnetron sputtering method using a Pt target in Ar gas at a pressure of 0.5 Pa, to obtain a magnetic recording medium. The substrate temperature during formation of the protective layer was room temperature (25° C.). The sputtering power during formation of the protective layer 60 was 50 W.

The M-H hysteresis loop of the resultant magnetic recording medium was measured with a PPMS apparatus (Physical Property Measurement System, manufactured by Quantum Design, Inc.). Saturated magnetization Ms, residual magnetization Mr, coercive force Hc and an α value of the M-H hysteresis loop were determined based on the obtained M-H hysteresis loop. The α value means a slope of the magnetization curve in the vicinity of the coercive force (H=Hc), and calculated by the equation of α=4π×(dM/dH). When determining the α value, a unit “emu/cm³” is used as the unit of M, and a unit “Oe” is used as the unit of H. The α value increases if the magnetic crystal grains in the magnetic recording layer 40 are not magnetically separated well. On the other hand, the α value decreases if the magnetic properties of the magnetic crystal grains vary greatly, in such a case where crystal grains caused by the secondary growth are present. The α value is preferably in a range of 0.75 or more and less than 3.0, and more preferably in a range of 0.9 or more and less than 2.0. Further, the magnetic anisotropy constant Ku of the obtained magnetic recording medium was determined by evaluating, with a PPMS apparatus, the dependence of spontaneous magnetization on the angle at which the magnetic field is applied. The methods described in the publications: R. F. Penoyer, “Automatic Torque Balance for Magnetic Anisotropy Measurements”, The Review of Scientific Instruments, August 1959, Vol. 30, No. 8, pp. 711-714; and Soshin Chikazumi, “Physics of ferromagnetism Vol. II”, Shokabo Co., Ltd., pp. 10-21 were used in determination of the magnetic anisotropy constant Ku. Here, the magnetic anisotropy constant Ku was obtained as a value of energy per the total volume of the magnetic crystal grains and the non-magnetic crystal grain boundary. Thus, a net magnetic anisotropy constant of the magnetic crystal grains Ku_grain was calculated. The net magnetic anisotropy constant Ku_grain was obtained by dividing the resultant magnetic anisotropy constant Ku with the ratio by volume of the magnetic crystal grains in the magnetic recording layer 50. The measurement results are shown in Table 2.

### COMPARATIVE EXAMPLES 1 to 6

Magnetic recording media were obtained by repeating similar procedures of those of Examples 1-6, except that the lower layer 51 was not formed, and the thickness of the upper layer was changed as described in Table 1. The properties of the magnetic recording media were evaluated by similar procedures to those in Examples 1-6. The measurement results are shown in Table 2.

### EXAMPLES 7 and 8

Magnetic recording media were obtained by repeating the procedure of Example 1, except that the thickness of the lower layer 51 was changed to 0.5 nm (Example 7) or 1.5 nm (Example 8). The thicknesses and the C contents of the lower layer 51 and the upper layer 52 are shown in Table 3. Further, the properties of the magnetic recording media were evaluated by similar procedures to those in Example 1. The measurement results are shown in Table 4.

TABLE 1
Constitution of Magnetic Recording Medium

| | | | | | Total |
|---|---|---|---|---|---|
| | | | | | thickness |
| | Lower layer | | Upper layer | | of the |
| | C | | C | | magnetic |
| | content | thickness | content | thickness | recording |
| | (vol. %) | (nm) | (vol. %) | (nm) | layer |
| Ex. 1 | 25 | 1 | 25 | 3 | 4 |
| Ex. 2 | 25 | 1 | 25 | 5 | 6 |
| Ex. 3 | 25 | 1 | 25 | 7 | 8 |
| Ex. 4 | 25 | 1 | 30 | 3 | 4 |
| Ex. 5 | 25 | 1 | 35 | 3 | 4 |
| Ex. 6 | 25 | 1 | 40 | 3 | 4 |
| C.Ex. 1 | — | — | 25 | 4 | 4 |
| C.Ex. 2 | — | — | 25 | 6 | 6 |
| C.Ex. 3 | — | — | 25 | 8 | 8 |
| C.Ex. 4 | — | — | 30 | 4 | 4 |
| C.Ex. 5 | — | — | 35 | 4 | 4 |
| C.Ex. 6 | — | — | 40 | 4 | 4 |

TABLE 2
Properties of Magnetic Recording Medium

| | Magnetic | | | | |
|---|---|---|---|---|---|
| | anisotropy | | | | |
| | constant | Saturated | Coercive | | |
| | Ku_grain*¹ | Magnetization | force | | Squareness |
| | (×10⁷ | Ms*² | Hc*³ | | ratio |
| | erg/cm³) | (emu/cm³) | (kOe) | α | Mr/Ms |
| Ex. 1 | 2.80 | 802 | 24.13 | 0.71 | 0.91 |
| Ex. 2 | 2.66 | 750 | 27.26 | 0.49 | 0.85 |
| Ex. 3 | 2.34 | 750 | 27.05 | 0.40 | 0.78 |
| Ex. 4 | 3.96 | 773 | 20.36 | 0.91 | 0.92 |
| Ex. 5 | 2.58 | 692 | 20.16 | 0.77 | 0.91 |
| Ex. 6 | 2.68 | 655 | 19.96 | 0.65 | 0.89 |
| C.Ex. 1 | 3.25 | 802 | 26.95 | 0.48 | 0.91 |
| C.Ex. 2 | 2.88 | 750 | 31.99 | 0.37 | 0.82 |
| C.Ex. 3 | 1.90 | 750 | 24.88 | 0.36 | 0.66 |
| C.Ex. 4 | 2.91 | 723 | 30.62 | 0.45 | 0.90 |
| C.Ex. 5 | 2.55 | 645 | 29.46 | 0.30 | 0.86 |
| C.Ex. 6 | 2.14 | 568 | 24.62 | 0.32 | 0.77 |

*¹10⁷ erg/cm³ = 1 J/cm³
*²1 emu/cm³ = 1 A/mm
*³1 kOe = 79.6 A/mm

TABLE 3
Constitution of Magnetic Recording Medium

| | | | | | Total |
|---|---|---|---|---|---|
| | | | | | thickness |
| | Lower layer | | Upper layer | | of the |
| | C | | C | | magnetic |
| | content | thickness | content | thickness | recording |
| | (vol. %) | (nm) | (vol. %) | (nm) | layer |
| C.Ex. 1 | — | — | 25 | 4 | 4 |
| Ex. 7 | 25 | 0.5 | 25 | 3.5 | 4 |
| Ex. 1 | 25 | 1 | 25 | 3 | 4 |
| Ex. 8 | 25 | 1.5 | 30 | 2.5 | 4 |

TABLE 4
Properties of Magnetic Recording Medium

| | Magnetic | | | | |
|---|---|---|---|---|---|
| | anisotropy | | | | |
| | constant | Saturated | Coercive | | |
| | Ku_grain*¹ | Magnetization | force | | Squareness |
| | (×10⁷ | Ms*² | Hc*³ | | ratio |
| | erg/cm³) | (emu/cm³) | (kOe) | α | Mr/Ms |
| C.Ex. 1 | 3.25 | 802 | 26.95 | 0.48 | 0.91 |
| Ex. 7 | 3.10 | 754 | 29.83 | 0.59 | 0.96 |
| Ex. 1 | 2.80 | 802 | 24.13 | 0.71 | 0.71 |
| Ex. 8 | 2.46 | 791 | 19.08 | 0.78 | 0.90 |

*¹10⁷ erg/cm³ = 1 J/cm³
*²1 emu/cm³ = 1 A/mm
*³1 kOe = 79.6 A/mm

(Evaluation)

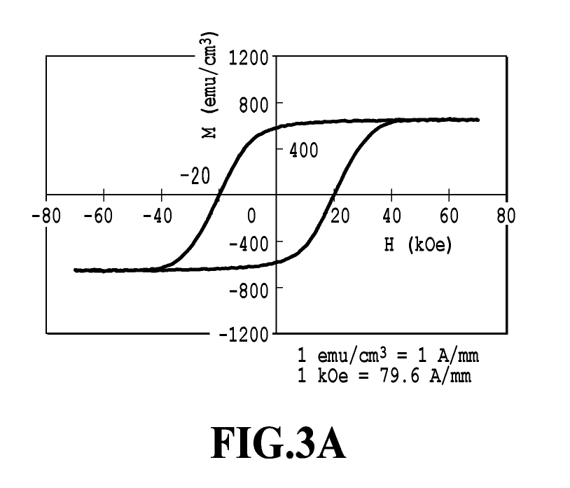

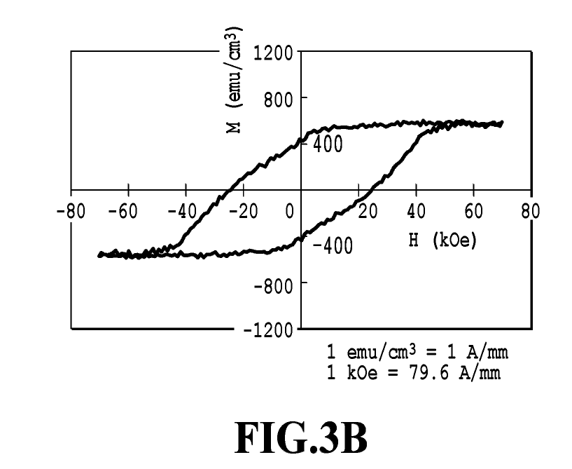

FIGS. 3A and 3B show the M-H hysteresis loops of the magnetic recording media obtained in Example 6 and Comparative Example 6. In the M-H hysteresis loop of the magnetic recording medium of Comparative Example 6, the smoothness of the curve is lost, and a hysteresis loop separated into two stages is observed. The reason of this result is considered that the columnar growth of the FePt magnetic crystal grains ceases at a certain thickness and subsequently the secondary growth of the FePt magnetic crystal grains occurs, in the FePt-C film formed without the use of Bi. On the other hand, in the M-H hysteresis loop of the magnetic recording medium of Example 6, the resultant curve is smooth and two-stage separation of the hysteresis loop is not observed. The reason of this result is considered that the secondary growth of the FePt magnetic crystal grains is inhibited by forming the lower layer 51 with the combinational use of Bi, and thereby the columnar growth of the FePt magnetic crystal grains occurs throughout the lower layer 51 and the upper layer 52.

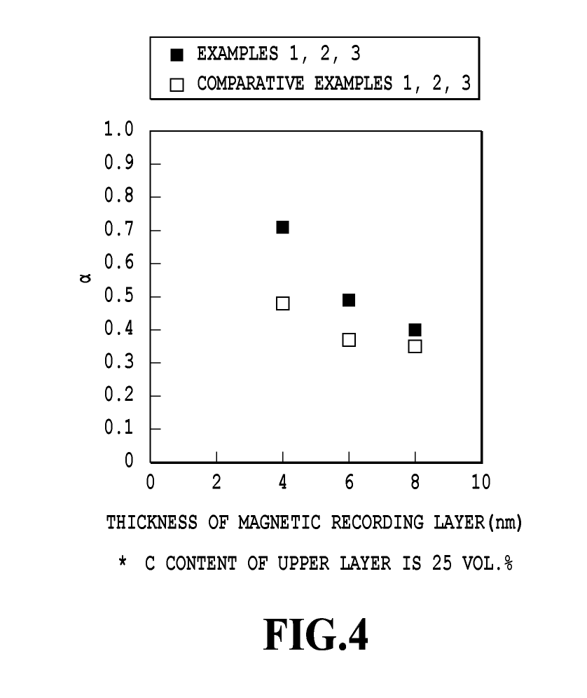

Next, influence of the thickness of the magnetic recording layer 50 will be explained, in the case where the thickness of the lower layer 51 was fixed to 1 nm and the thickness of the upper layer 52 was changed. Here, the C content in the upper layer 52 was fixed to 25% by volume. FIG. 4 shows a relationship between the thickness of the magnetic recording layer 50 and the α value, for the magnetic recording media of Examples 1, 2 and 3 in which the lower layer 51 was formed with the combinational use of Bi, and the magnetic recording media of Comparative Examples 1, 2 and 3 in which the lower layer was not formed. The α values of Examples 1, 2 and 3 is larger than those of Comparative Examples 1, 2 and 3, in all thickness, although the α value decreases as the thickness of the magnetic recording layer 50 increases. It is understood from the above results that formation of the lower layer 51 with the combinational use of Bi is effective in promoting magnetic separation of the FePt magnetic crystal grains and inhibiting the secondary growth.

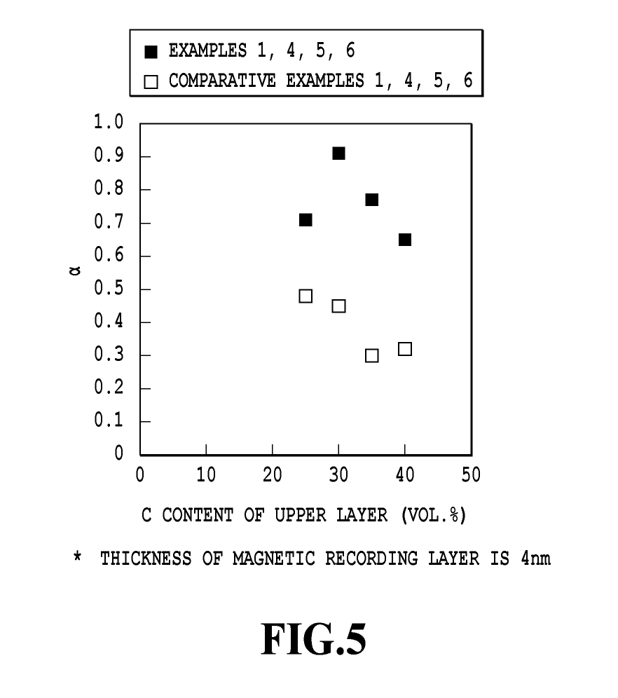

Next, influence of the C content in the upper layer 52 will be explained. In Examples, the thicknesses of the lower layer 51 and the upper layer 52 were fixed to 1 nm and 3 nm, respectively. In Comparative Examples, examples having the magnetic recording layer 50 of the same thickness of 4 nm as that of Examples are used for comparison. FIG. 5 shows a relationship between the C content in the upper layer 52 and the α value, for the magnetic recording media of Examples 1, 4, 5 and 6 in which the lower layer 51 was formed with the combinational use of Bi, and the magnetic recording media of Comparative Examples 1, 4, 5 and 6 in which the lower layer was not formed. In the magnetic recording media of Comparative Examples 1, 4, 5 and 6 in which the lower layer was not formed, the α value decreases as the C content in the upper layer 52 increases. On the other hand, in Examples 1, 4, 5 and 6 in which the lower layer 51 was formed with the combinational use of Bi, no apparent correlation is observed between the C content in the upper layer 52 and the α value. The α values of Examples 1, 4, 5 and 6 is larger than those of Comparative Examples 1, 4, 5 and 6, in all C contents. It is also understood from the above results that formation of the lower layer 51 with the combinational use of Bi is effective in promoting magnetic separation of the FePt magnetic crystal grains and inhibiting the secondary growth.

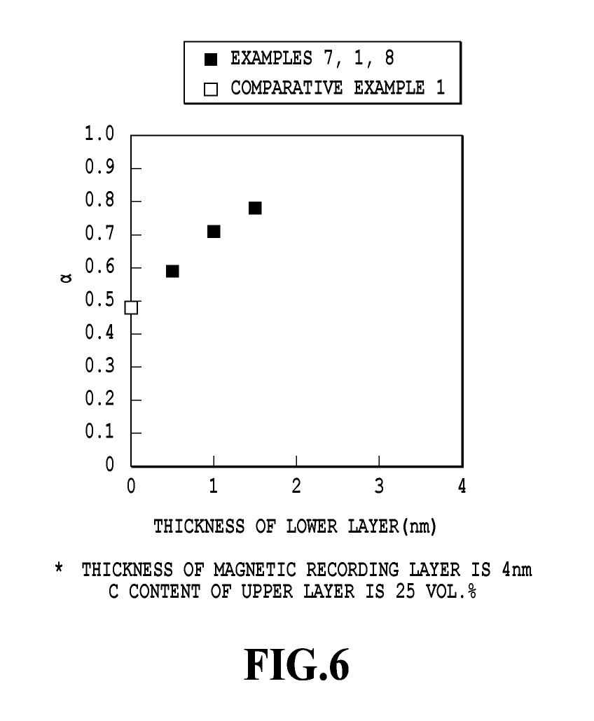

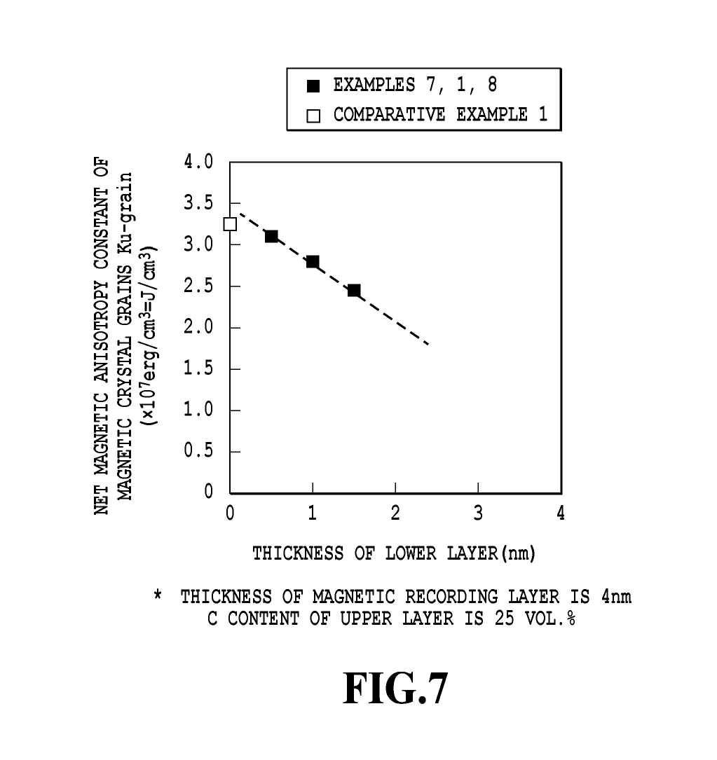

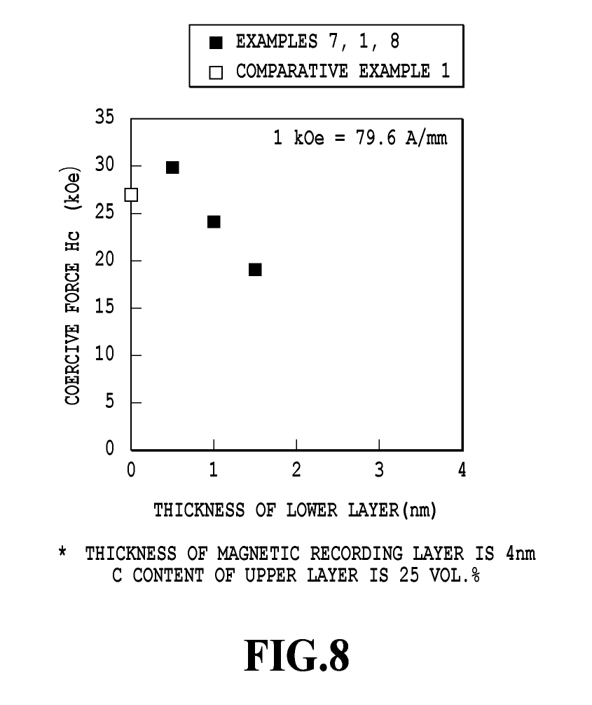

Next, influence of the thickness of the lower layer 51 formed with the combinational use of Bi will be explained. Here, the thickness of the magnetic recording layer 50 was fixed to 4 nm by changing the thickness of the upper layer 52, and the C content in the upper layer 52 was fixed to 25% by volume. FIG. 6 shows a relationship between the thickness of the lower layer 51 and the a value, FIG. 7 shows a relationship between the thickness of the lower layer and the net magnetic anisotropy constant of magnetic crystal grains Ku_grain, and FIG. 8 shows relationship between the thickness of the lower layer 51 and the coercive force Hc, for the magnetic recording media of Examples 7, 1 and 8 in which the lower layer 51 was formed with the combinational use of Bi, and the magnetic recording medium of Comparative Example 1 in which the lower layer 51 was not formed. As understood from FIG. 6, the α value comes close to one (1) as the thickness of the lower layer 51 increases, and thus the magnetic crystal grains are magnetically separated well and the secondary growth of the magnetic crystal grains is inhibited. On the other hand, as understood from FIGS. 7 and 8, there is a tendency for Ku_grain and the coercive force Hc to decrease as the thickness of the lower layer 51 increases. Generally, Ku_grain of not less than 1.5×10⁷ erg/cm³ (1.5 J/cm³) is necessary to achieve a magnetic recording density of greater than 1 terabits per square inch (Tbpsi). From extrapolation of the data of FIG. 7, it is understood that the thickness of the lower layer 51 is preferably not greater than about 3 nm, for achieving Ku_grain of not less than 1.5×10⁷ erg/cm³ (1.5 J/cm³).

Further, the atomic distribution in the thickness direction of the magnetic recording medium of Example 1 was analyzed by X-ray photoelectron spectroscopy (ESCA). From the result, it is understood that about 0.1 atom % of Bi, based on the total atoms of the magnetic recording layer 50, remains in the magnetic recording layer 50 formed at a temperature of 430° C. The remaining amount of Bi is remarkably smaller than the amount of Bi reaching the surface of the stacked body during formation of the lower layer 51. From this result, it is understood that re-evaporation and the like of Bi occur during formation of the magnetic recording layer 50. It is preferable to rise the temperature during formation of the magnetic recording layer 50, that is, the lower layer 51 and the upper layer 52. This is because it is preferable to reduce the remaining amount of Bi as possible for preventing decrease in saturated magnetization Ms and loss in magnetic spacing, and ordering of the ordered alloy in the magnetic crystal grains is promoted.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. All of the patent applications and documents cited herein are incorporated herein by reference in their entirety.

What is claimed is:

1. A magnetic recording medium comprising a substrate and a magnetic recording layer comprising a lower layer and an upper layer, wherein:
the lower layer and the upper layer comprise magnetic crystal grains consisting of an ordered alloy and a non-magnetic crystal grain boundary;
the lower layer is formed by depositing Bi, C, and elements that constitute the ordered alloy; and
the upper layer is formed by depositing C and elements that constitute the ordered alloy.

2. The magnetic recording medium according to claim 1, wherein the ordered alloy comprises at least one element selected from the group consisting of Fe and Co, and at least one element selected from the group consisting of Pt, Pd, Au, and Ir.

3. The magnetic recording medium according to claim 2, wherein the ordered alloy further comprises at least one element selected from the group consisting of Ni, Mn, Cu, Ag, Au, Ru and Cr.

4. The magnetic recording medium according to claim 1, wherein the ordered alloy is L1₀ type FePt.

5. The magnetic recording medium according to claim 1, wherein the lower layer has a thickness of 0.1 nm or more and 3 nm or less.

6. A method for producing a magnetic recording medium comprising the steps of:
preparing a substrate;
sputtering Bi, C, and element that constitute an ordered alloy to form a lower layer of a magnetic recording layer; and
sputtering C and the element that constitute the ordered alloy to form an upper layer of the magnetic recording layer.

7. The method for producing the magnetic recording medium according to claim 6, wherein the lower layer and the upper layer of the magnetic recording layer comprise magnetic crystal grains consisting of the ordered alloy and a non-magnetic crystal grain boundary comprising C.

8. The method for producing the magnetic recording medium according to claim 6, wherein the ordered alloy comprises at least one element selected from the group consisting of Fe and Co, and at least one element selected from the group consisting of Pt, Pd, Au, and Ir.

9. The method for producing the magnetic recording medium according to claim 8, wherein the ordered alloy further comprises at least one element selected from the group consisting of Ni, Mn, Cu, Ag, Au, Ru and Cr.

10. The method for producing the magnetic recording medium according to claim 6, wherein the ordered alloy is L1₀ type FePt.

11. The method for producing the magnetic recording medium according to claim 6, wherein the lower layer has a thickness of 0.1 nm or more and 3 nm or less.
